(19) United States
(12) Patent Application Publication
(10) Pub. No.: US 2015/0216081 A1
(43) Pub. Date: Jul. 30, 2015

(54) HEAT DISSIPATION MECHANISM FOR HANDHELD ELECTRONIC APPARATUS

(71) Applicant: Tsung-Hsien Huang, I-Lan Hsien (TW)

(72) Inventor: Tsung-Hsien Huang, I-Lan Hsien (TW)

(21) Appl. No.: 14/251,572

(22) Filed: Apr. 12, 2014

(30) Foreign Application Priority Data
Jan. 24, 2014 (CN) 201410034347.8

(51) Int. Cl. H05K 7/20

(52) U.S. Cl. CPC H05K 7/20336; H05K 7/2039

(57) ABSTRACT

A heat dissipation mechanism for handheld electronic apparatus includes a thin metal sheet having one or multiple elongated mounting grooves and an elongated rib extending along each of two opposite lateral sides of each elongated mounting groove, and one or multiple heat pipes respectively press-fitted into one respective elongated mounting groove of the thin metal sheet. After insertion of each heat pipe into one respective elongated mounting groove, the elongated ribs are deformed to wrap about each loaded heat pipe.

### BACKGROUND OF THE INVENTION

(a) Field of the Invention

The present invention relates to heat dissipation technology, and more particularly to a heat dissipation mechanism for handhold electronic apparatus, which comprises a thin metal sheet and at least one heat pipe joined to the thin metal sheet.

(b) Description of the Prior Art

With rapid progress of technology, many different handheld electronic apparatuses, such as cell phone, notebook computer, tablet computer, iPad, PDA, GPS etc., have been continuously created. These advanced handheld electronic apparatuses have the characteristics of low profile, light weight and compact size. Further, due to high operating speed, the internal CPU and other IC components of these advanced handheld electronic apparatuses generate a large amount of waste heat during operation. Such waste heat must be quickly dissipated to ensure normal functioning of the heat emitting component and to sustain its lifespan.

In order to fit the low-profile characteristic of a handheld electronic apparatus, conventional heat dissipation mechanisms commonly comprise a thin metal sheet for directly bonding to a CPU or heat-emitting component of a handheld electronic apparatus for heat dissipation. This technique has low heat dissipation performance and cannot dissipate heat rapidly. Waste heat can easily be accumulated in the handheld electronic apparatus, causing system halt or component damage.

### SUMMARY OF THE INVENTION

The present invention has been accomplished under the circumstances in view. It is therefore the main object of the present invention to provide a heat dissipation mechanism for handheld electronic apparatus that comprises a thin metal sheet and at least one heat pipe mounted at the thin metal sheet. The thin metal sheet comprises at least one elongated mounting groove adapted for receiving the at least one heat pipe, and an elongated rib extending along at least one of two opposite lateral sides of each elongated mounting groove and deformable to wrap about the associated heat pipe. After installation of the heat dissipation mechanism in a handheld electronic apparatus, the heat absorbing end of each heat pipe is kept in contact with a heat-emitting component of the handheld electronic apparatus, enabling heat to be rapidly carried away from the heat-emitting component. Thus, the heat dissipation mechanism enhances the heat dissipation performance of the handheld electronic apparatus, avoiding damage to the handheld electronic apparatus or its components.

Further, each heat pipe is a flat heat pipe having a flat surface thereof exposed to the outside and kept flush with the surface of the thin metal sheet. Thus, the heat dissipation mechanism is easy to fabricate, and its cost is low. Further, the heat pipe(s) can be tightly secured to the thin metal sheet by the elongated ribs without welding.

Further, each elongated mounting groove of the thin metal sheet can be made in the form of a straight groove, angled groove or U-shaped groove for the mounting of one respective straight heat pipe, angled heat pipe or U-shaped heat pipe.

### BRIEF DESCRIPTION OF THE DRAWINGS

FIG. 1 is an exploded view of a heat dissipation mechanism for handheld electronic apparatus in accordance with a first embodiment of the present invention.

FIG. 2 is a perspective view of the first embodiment of the present invention, illustrating the heat pipe press-fitted into the elongated mounting groove prior to deformation of the elongated ribs.

FIG. 3 is a schematic sectional view in an enlarged scale of a part of FIG. 2, illustrating the heat pipe set in the elongated mounting groove.

FIG. 4 corresponds to FIG. 2, illustrating the deformed elongated ribs.

FIG. 5 corresponds to FIG. 3, illustrating the deformed elongated ribs.

FIG. 6 is an exploded view illustrating the use of the heat dissipation mechanism in a cell phone in accordance with the first embodiment of the present invention

FIG. 7 is a top view of a heat dissipation mechanism for handheld electronic apparatus in accordance with a second embodiment of the present invention.

FIG. 8 is a top view of a heat dissipation mechanism for handheld electronic apparatus in accordance with a third embodiment of the present invention.

FIG. 9 is a top view of a heat dissipation mechanism for handheld electronic apparatus in accordance with a fourth embodiment of the present invention.

FIG. 10 is a top view of a heat dissipation mechanism for handheld electronic apparatus in accordance with a fifth embodiment of the present invention.

### DETAILED DESCRIPTION OF THE PREFERRED EMBODIMENTS

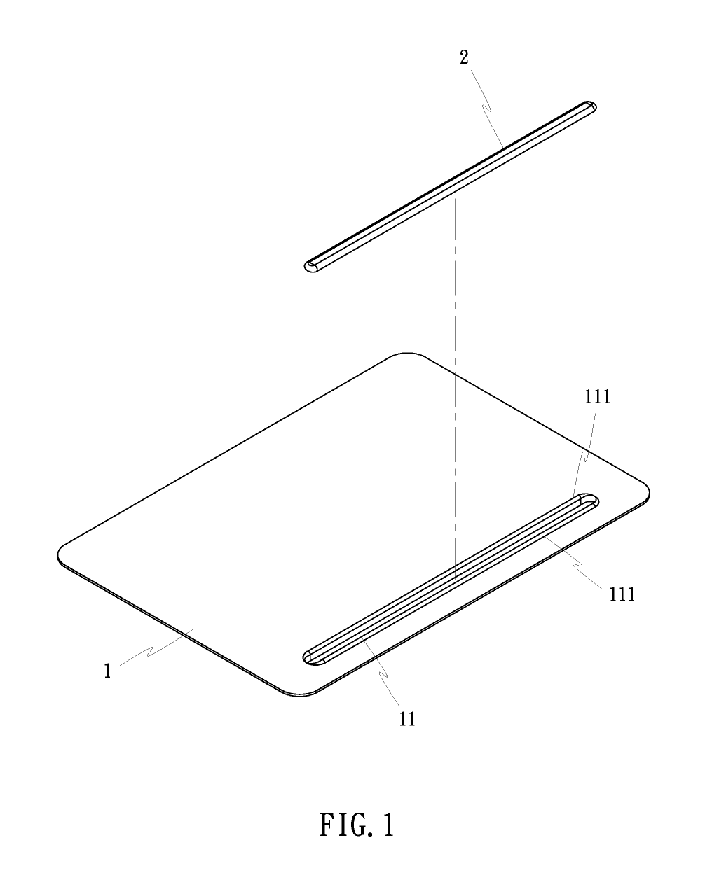

Referring to FIGS. 1-5, a heat dissipation mechanism for handhold electronic apparatus in accordance with a first embodiment of the present invention is shown. As illustrated, the heat dissipation mechanism comprises a thin metal sheet 1 and a heat pipe 2.

The thin metal sheet 1, as illustrated in FIG. 1, is a metal sheet having high heat transfer capability. The thin metal sheet 1 is stamped to provide an elongated mounting groove 11 fitting the configuration of the heat pipe 2, and an elongated rib 111 extending along each of two opposite lateral sides of the elongated mounting groove 11.

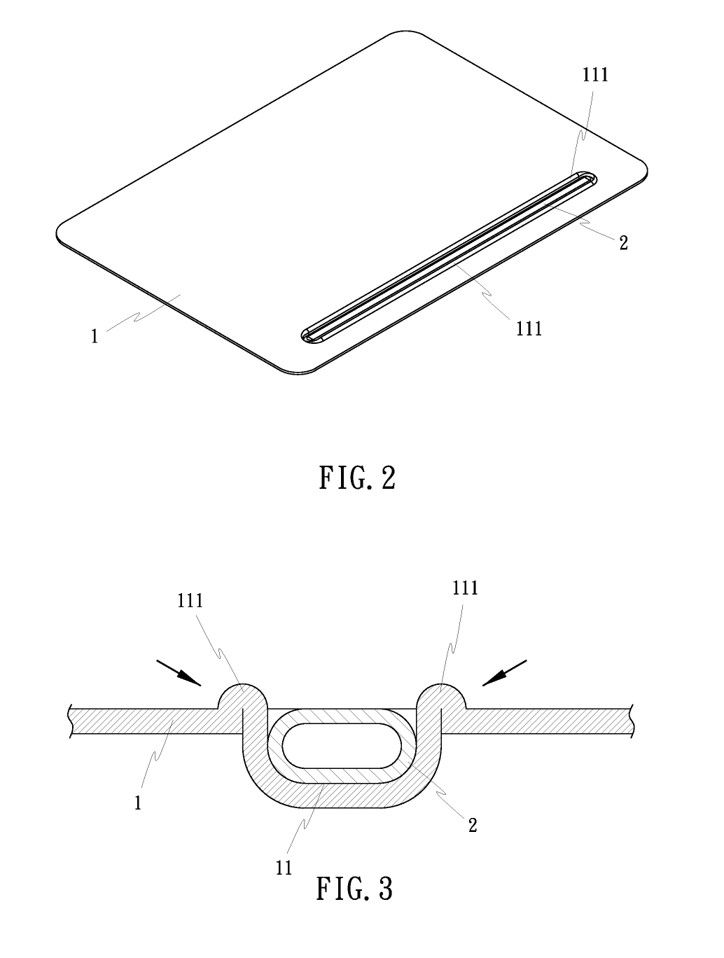

The heat pipe 2 is a flat pipe fitted into the mounting groove 11 of the thin metal sheet 1 (see FIG. 2).

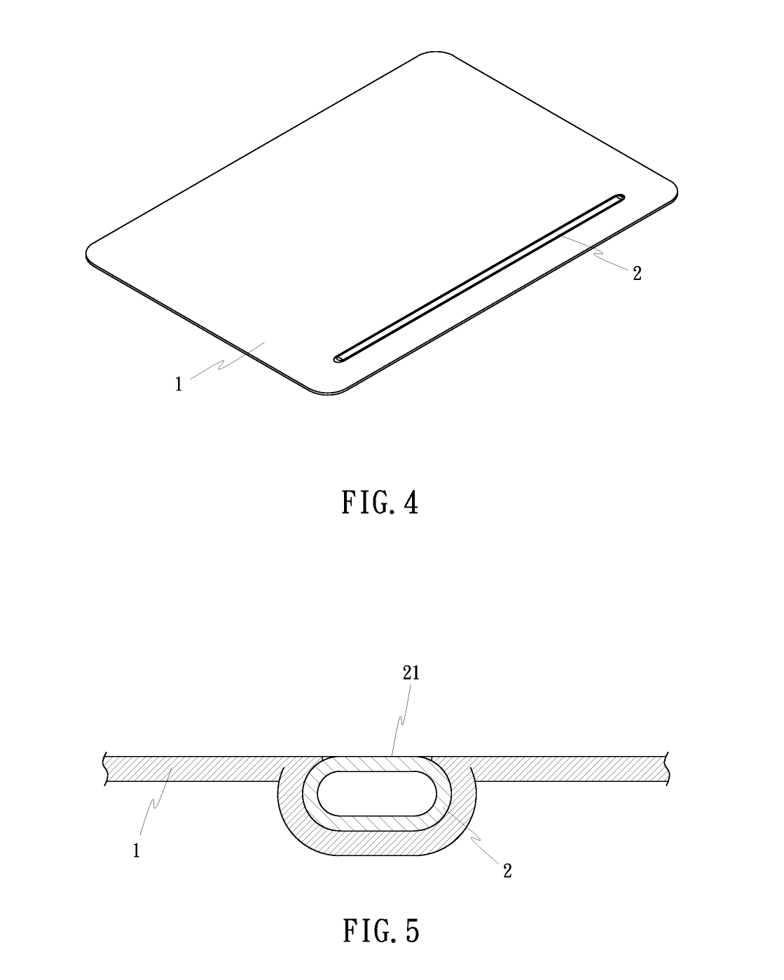

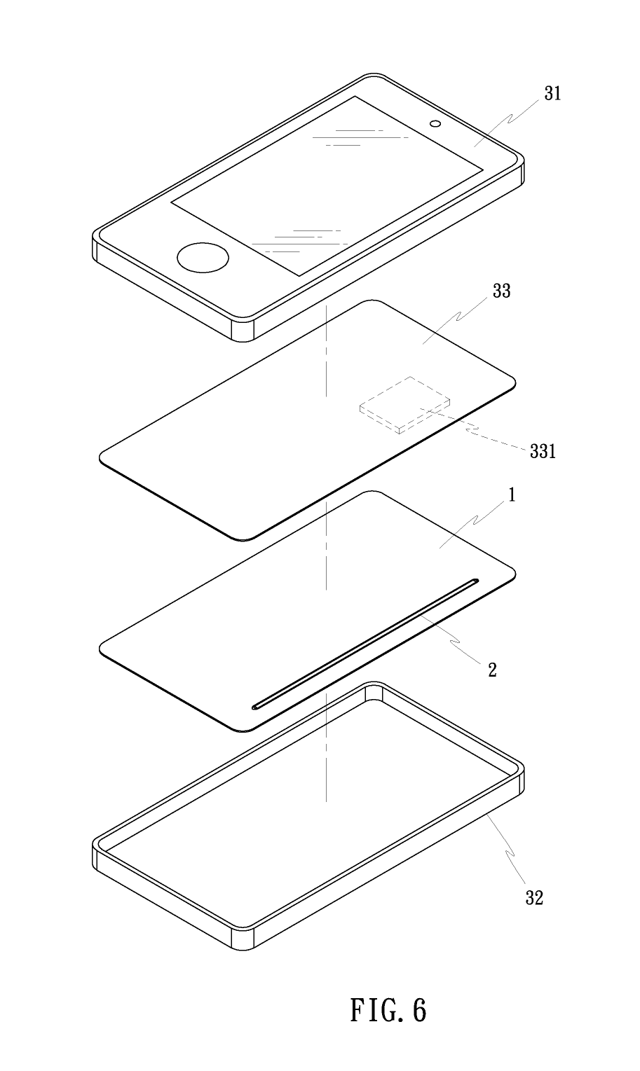

After insertion of the heat pipe 2 into the mounting groove 11, the elongated ribs 111 are deformed (in the direction shown in FIG. 3) to wrap about the heat pipe 2 (see FIG. 4 and FIG. 5). After installation, the exposed surface 21 of the heat pipe 2 is kept flush with the surface of the thin metal sheet 1. Thus, the heat pipe 2 is tightly embedded in the thin metal sheet 1.

Referring to FIG. 6, in one application example of the present invention, the heat dissipation mechanism is used in a cell phone. As illustrated, the cell phone comprises a top cover 31, a bottom cover 32, a circuit board 33 set in between the top cover 31 and the bottom cover 32 and carrying a heat-emitting component 331 (for example, CPU). The heat dissipation mechanism is set between the circuit board 33 and the bottom cover 32 to keep the heat absorbing end of the heat pipe 2 in direct contact with the heat-emitting component 331. Thus, the heat pipe 2 can absorb heat from the heat-emitting component 331 and transfer absorbed heat to the thin metal sheet 1 for quick dissipation, preventing accumulation of waste heat in the cell phone. Thus, the use of the heat dissipation mechanism enhances the heat dissipation performance of the cell phone, avoiding damage to the cell phone or its components.

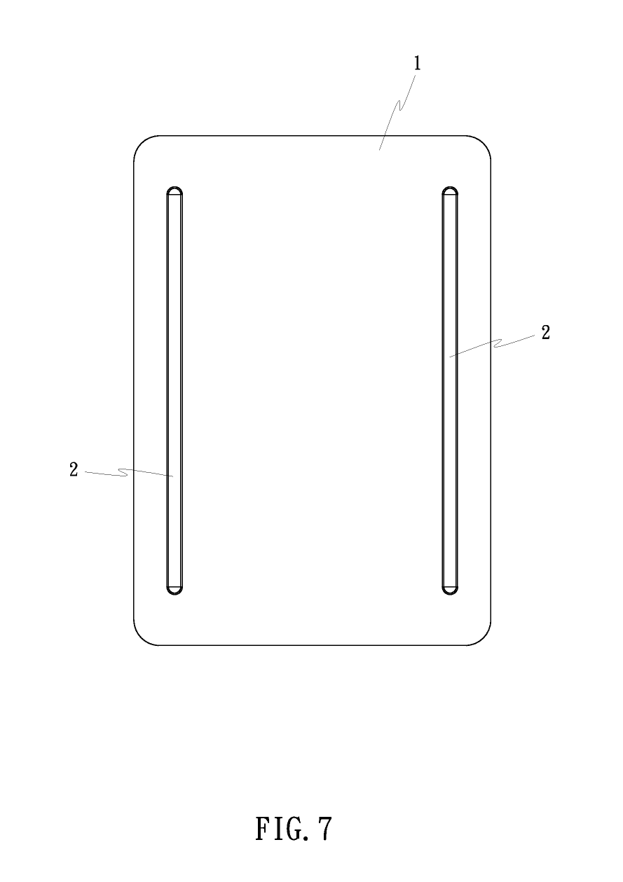

FIG. 7 illustrates a heat dissipation mechanism for handhold electronic apparatus in accordance with a second embodiment of the present invention. This second embodiment is substantially similar to the aforesaid first embodiment with the exception that two heat pipes 2 are respectively press-fitted into respective elongated mounting grooves near two opposite lateral sides of the thin metal sheet 1 and firmly secured thereto by respective elongated ribs.

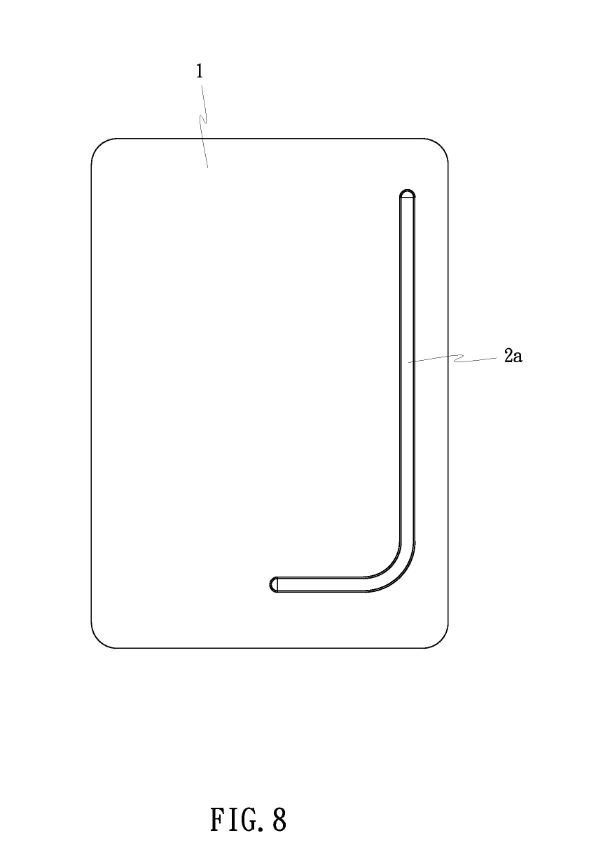

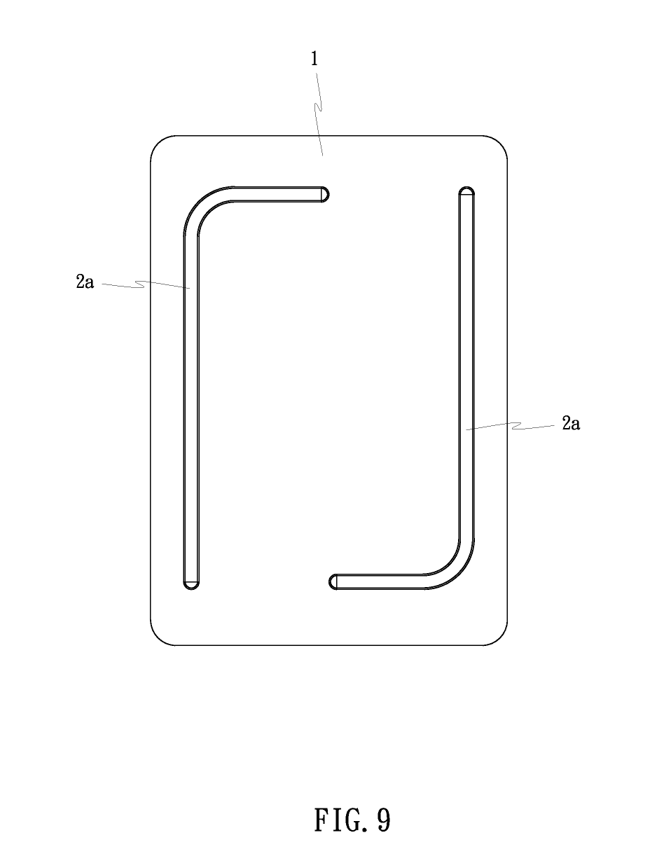

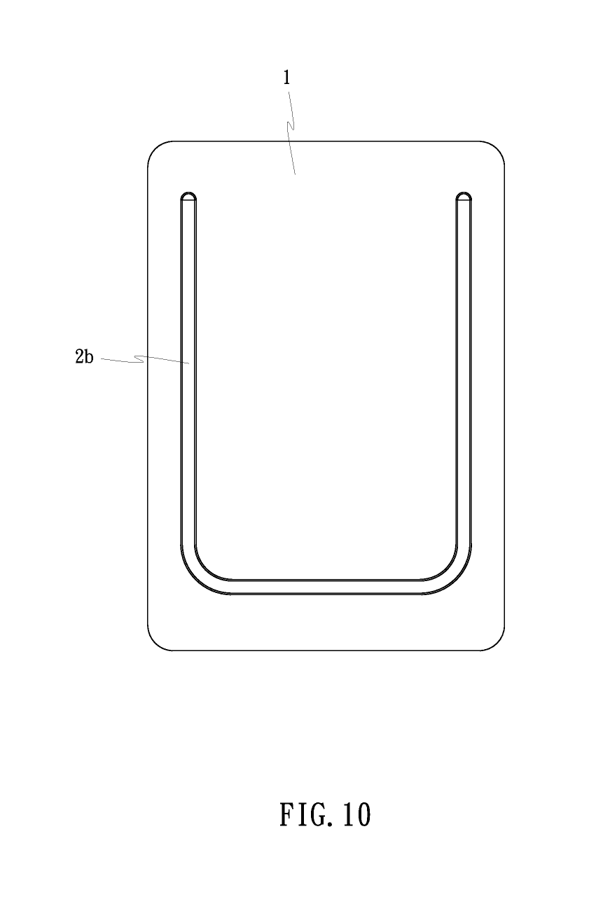

FIGS. 8-10 illustrate many other alternate forms of the heat dissipation mechanism for handhold electronic apparatus in accordance with the present invention. As illustrated, the thin metal sheet 1 can be configured to provide one or multiple elongated mounting grooves for securing one or multiple straight heat pipes 2, one or multiple angled heat pipes 2a or a U-shaped heat pipe 2b. Further, the at least one elongated mounting groove of the thin metal sheet 1 is configured according to the configuration of the at least one straight heat pipe 2, angled heat pipe 2a or U-shaped heat pipe 2b.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A heat dissipation mechanism for a handheld electronic apparatus, comprising a thin metal sheet and at least one heat pipe mounted at said thin metal sheet, wherein:
said thin metal sheet comprises at least one elongated mounting groove adapted for receiving said at least one heat pipe, and an elongated rib extending along at least one of two opposite lateral sides of each said elongated mounting groove and deformed to wrap about one said heat pipe.

2. The heat dissipation mechanism as claimed in claim 1, wherein each said heat pipe has a flat surface thereof exposed to the outside and kept flush with said thin metal sheet.

3. The heat dissipation mechanism as claimed in claim 1, wherein each said heat pipe has a heat absorbing end thereof for making direct contact with a heat-emitting component of said handheld electronic apparatus.

4. The heat dissipation mechanism as claimed in claim 1, wherein each said heat pipe is a straight heat pipe.

5. The heat dissipation mechanism as claimed in claim 1, wherein each said heat pipe is an angled heat pipe.

6. The heat dissipation mechanism as claimed in claim 1, wherein each said heat pipe is a U-shaped heat pipe.

7. The heat dissipation mechanism as claimed in claim 1, wherein each said heat pipe is a flat heat pipe.
